(19) United States
(12) Patent Application Publication
(10) Pub. No.: US 2025/0157945 A1
(43) Pub. Date: May 15, 2025

(54) Chip Package Structure and Manufacturing Method Therefor

(71) Applicant: Huawei Technologies Co., Ltd., Shenzhen (CN)

(72) Inventors: Xuan Wang, Shanghai (CN); Po Shi, Shanghai (CN); Zhengde Yang, Shanghai (CN); Yongsheng Li, Shanghai (CN)

(21) Appl. No.: 19/024,776

(22) Filed: Jan. 16, 2025

Related U.S. Application Data
(63) Continuation of application No. PCT/CN2023/104232, filed on Jun. 29, 2023.

(30) Foreign Application Priority Data
Jul. 30, 2022 (CN) 202210911481.6

(51) Int. Cl. H01L 23/552; H01L 21/56; H01L 21/77; H01L 23/498; H01L 23/538; H01L 25/065; H01L 25/16; H10B 80/00; H10D 80/30

(52) U.S. Cl. CPC H01L 23/552; H01L 21/565; H01L 21/77; H01L 23/49822; H01L 23/49838; H01L 23/5383; H01L 23/5386; H01L 25/0655; H01L 25/167; H10B 80/00; H10D 80/30

(57) ABSTRACT

A chip package structure includes a substrate, a chip, and a shielding layer. The substrate includes a plurality of stacked metal layers. A first conductive column runs through at least two metal layers, and has a first contact surface that is exposed to an outer side of the substrate and that faces a top surface of the substrate. The chip is disposed on the top surface of the substrate. The shielding layer is formed outside the chip, and is connected to the first conductive column through the first contact surface, and the shielding layer is grounded. In the chip package structure, the shielding layer is connected to the first conductive column through contact with the first contact surface, and is grounded to form an electromagnetic shielding cavity.

### CROSS-REFERENCE TO RELATED APPLICATIONS

This is a continuation of International Patent Application No. PCT/CN2023/104232,filed on Jun. 29, 2023, which claims priority to Chinese Patent Application No. 202210911481.6, filed on Jul. 30, 2022. The disclosures of the aforementioned applications are hereby incorporated by reference in their entireties.

### TECHNICAL FIELD

This disclosure relates to the field of chip packaging technologies, and in particular, to a chip package structure and a manufacturing method therefor.

### BACKGROUND

With the continuous development of systematization and miniaturization of semiconductor products, a growing quantity of electronic components needs to be integrated in a limited size. A system in package (SIP) is a single standard chip package structure obtained by assembling a plurality of active electronic components, passive electronic components, and components such as micro-electromechanical systems (MEMS) or optical components with different functions.

An electromagnetic sensitive component or an electromagnetic interference source may exist inside the SIP, and therefore self-shielding needs to be implemented on the SIP, to greatly reduce interference to the electromagnetic sensitive component inside the SIP and reduce interference from the interference source inside the SIP to electronic components outside the SIP.

Electromagnetic interference (EMI) shielding is usually formed outside the electronic components of the SIP and interconnection circuits, to suppress interference from the electronic components inside the SIP to the outside and reduce interference from an interference source outside the SIP to the electronic components inside the SIP. However, effect of contact between parts (metals of different parts) that form the shielding has poor reliability, affecting shielding effect in long-term use.

### SUMMARY

Embodiments of this disclosure provide a chip package structure, a manufacturing method therefor, and an electronic device. An objective is to provide a chip package structure having a reliable and excellent electromagnetic self-shielding function, and a method for manufacturing the chip package structure. When the chip package structure is used in an electronic device, electronic components of the chip package structure can effectively reduce electromagnetic interference, and can also reduce interference from the electronic device to other electronic components.

According to a first aspect, an embodiment provides a chip package structure. The chip package structure may be a standard SIP product, or may be a chip package product of another type. The chip package structure includes a substrate, a chip, and a shielding layer. The substrate includes a plurality of stacked metal layers. A first conductive column runs through at least two metal layers, and the first conductive column has a contact surface exposed to an outer side of the substrate, where the contact surface includes a first contact surface that faces a top surface of the substrate. The chip is disposed on the top surface of the substrate, and is connected to a metal layer on the top surface of the substrate. The shielding layer is formed outside the chip, and is connected to the first conductive column through the first contact surface, and the shielding layer is grounded. In the chip package structure, the shielding layer is connected to the first conductive column through the first contact surface, and is grounded, so as to form an electromagnetic shielding cavity. The chip is mounted in the electromagnetic shielding cavity, so that electromagnetic radiation generated by the chip and an external electromagnetic wave can be shielded, thereby reducing interference to the chip.

Based on a process for forming the shielding layer, for example, a sputtering process, because the first contact surface faces the top surface of the substrate, the shielding layer formed on the first contact surface is thicker, so that the shielding layer and the first conductive column have better contact effect, resistance is lower, and the shielding layer and the first conductive column are not easily out of contact with each other, so that electromagnetic leakage does not easily occur.

In a possible implementation of the first aspect, the shielding layer is grounded through the at least two metal layers through which the first conductive column runs.

In a possible implementation of the first aspect, at least one metal layer through which the first conductive column runs is connected to a metal layer on a bottom surface of the substrate, and the metal layer on the bottom surface is configured for grounding. Because the metal layer on the bottom surface of the substrate includes a grounding circuit, the shielding layer may be grounded through the grounding circuit. For example, the grounding circuit on the bottom surface of the substrate is grounded by connecting a ground signal on a mainboard in the electronic device.

It should be noted that the metal layer on the bottom surface of the substrate and the metal layer on the top surface of the substrate include interconnection lines, and the interconnection lines may be metal wiring layers.

In a possible implementation of the first aspect, the first conductive column further includes a second contact surface exposed to the outer side of the substrate, and a corner is formed between the second contact surface and the first contact surface; and the shielding layer is electrically connected to the first conductive column through the first contact surface and the second contact surface. First, when the shielding layer is formed through sputtering, the shielding layer deposited on the first contact surface is thicker, so that contact reliability between the shielding layer and the first conductive column is higher and resistance is lower, thereby achieving better shielding effect and better reliability. Second, the shielding layer is further deposited on the second contact surface, that is, the shielding layer is in contact with the two surfaces of the first conductive column. Therefore, the contact effect between the shielding layer and the first conductive column can be further optimized. In this way, a possibility of electromagnetic leakage caused by poor contact between the shielding layer and the first conductive column can be further reduced.

In a possible implementation of the first aspect, the chip package structure further includes a molding formed on the top surface of the substrate, and the chip is wrapped in the molding, and the shielding layer covers an outer surface of the molding, the first contact surface, and a side surface area that is of the substrate and that is located between the first contact surface and the top surface of the substrate. In other words, the shielding layer does not cover all side surface areas of the substrate. Because a combination of an electromagnetic shielding material used for the shielding layer and a material of the substrate usually has poor reliability during collision, the shielding layer is formed only on the outer surface of the molding, the first contact surface, and the side surface area that is of the substrate and that is located between the first contact surface and the top surface of the substrate. Compared with forming a shielding layer in all side surface areas of the substrate, most of outer side surfaces of the substrate are not covered by the shielding layer, so that a risk that shielding performance is reduced due to detachment of the shielding layer caused by collision is reduced.

In a possible implementation of the first aspect, the metal layers through which the first conductive column runs are all located inside the substrate and at least one metal layer through which the first conductive column runs is connected to the metal layer on the bottom surface of the substrate through a second conductive column, and in a direction parallel to the top surface of the substrate, a distance between the second conductive column and a side that is of the first conductive column and that is away from the outer side of the substrate is greater than a first distance. In other words, the second conductive column is wrapped in an insulation material of the substrate, or the second conductive column is located inside the substrate. It is easily understood that, when the first conductive column runs through the metal layer on the bottom surface of the substrate, the first conductive column may be directly grounded through the metal layer. An objective of this implementation is to provide a grounding manner when the metal layers through which the first conductive column runs are all located inside the substrate. The shielding layer is connected to the second conductive column through the metal layers through which the first conductive column runs, and then the second conductive column runs through the metal layer on the bottom surface of the substrate, so as to connect to the ground on the mainboard, e.g. a printed circuit board (PCB), in the electronic device through the metal layer on the bottom surface of the substrate. In addition, it should be noted that, in this implementation, as a part that forms the fully sealed electromagnetic shielding cavity, because the second conductive column is located inside the substrate, it means that there is no need to form shielding layers on all the side surface areas of the substrate, so as to reduce a possibility that the shielding layer falls off due to poor reliability of a combination between the shielding layer and the substrate, that is, enhancing reliability of the electromagnetic shielding function. In a possible implementation of the first aspect, different metal layers are separated by an insulation layer formed by an insulation material. The insulation material may be a substrate panel material such as polypropylene or ceramic.

In a possible implementation of the first aspect, the plurality of metal layers includes a plurality of first metal layers and at least one second metal layer that are consecutively disposed. Herein, a difference between the first metal layer and the second metal layer lies in that, in the direction parallel to the top surface of the substrate, an edge of the first metal layer extends to an outer edge of the substrate, and a distance between an edge of the second metal layer and the side that is of the first conductive column and that is away from the outer side of the substrate is greater than a second distance, and the second distance is less than the first distance. The first conductive column runs through the at least two first metal layers. Alternatively, it may be understood that, none of peripheral edges of the second metal layer are exposed outside the substrate, but are isolated from the outside through an insulation material of the substrate, and the first conductive column does not run through the second metal layer. The chip package structure provided in this disclosure is obtained through cutting from a plurality of integrally formed package structures, and a side surface of the chip package structure is a cut surface formed during cutting. Therefore, in this implementation, that none of the peripheral edges of the second metal layer are exposed outside the substrate means that the second metal layer is not cut during cutting. However, because a larger quantity of metal layers that are cut indicates larger abrasion caused to a dicing blade, costs can be reduced in this implementation.

In a possible implementation of the first aspect, there are a plurality of second metal layers, at least two second metal layers are consecutively disposed, and the second conductive column runs through the at least two consecutive second metal layers. In this implementation, the second conductive column has two functions: one is to connect one of the metal layers through which the first conductive column runs to the metal layer on the bottom surface of the substrate; and the other is to implement electrical interconnections between the plurality of second metal layers through which the second conductive column runs. Alternatively, it may be understood that, in this embodiment, the second conductive column in the substrate is reused, and is used to implement grounding of the shielding layer based on an original electrical interconnection function of the second conductive column, or is used as a part that forms the electromagnetic shielding cavity.

In a possible implementation of the first aspect, the insulation layer includes a core plate; and the first conductive column is located on a side that is of the core plate and that is close to the chip, and a second metal layer is located on a side that is of the core plate and that is away from the chip. In other words, the core plate divides the substrate into two parts, an upper part and a lower part, and the first conductive column is located on the upper part of the substrate. This implementation aims to reduce, to the greatest extent, the side surface area that is of the substrate and that needs to be covered by the shielding layer, so as to reduce a possibility that the shielding layer falls off due to poor reliability of a combination between the shielding layer and the substrate, that is, enhancing reliability of the electromagnetic shielding cavity.

Further, assuming that the first conductive column is located on the lower part of the substrate, it means that the shielding layer needs to cover a side surface area corresponding to the upper part of the substrate and a side surface area of the core plate before extending to the first contact surface exposed by the first conductive column. If the first conductive column is located on the upper part of the substrate, the shielding layer does not need to cover the foregoing side surface areas, and therefore side surface areas that are of the substrate and that need to be covered by the shielding layer can be reduced.

In a possible implementation of the first aspect, a plurality of first conductive columns disposed on a first side of the substrate is distributed on a first straight line parallel to a boundary line of the first side, or distances between the first straight line and the plurality of first conductive columns disposed on the first side of the substrate are within a preset distance range, and the first side is any side of the substrate. For beneficial effects of this implementation, refer to technical effects of distribution types of a plurality of first conductive columns in the following second aspect.

According to a second aspect, an embodiment provides a method for manufacturing a chip package structure. In the manufacturing method, a to-be-cut integrated package structure is first obtained, where the integrated package structure includes a plurality of integrally formed substrates and a chip disposed on a top surface of each substrate, and each substrate includes a plurality of first conductive columns and a plurality of stacked metal layers, and each first conductive column runs through at least two metal layers. Then, first cutting is performed on the integrated package structure. An objective of the first cutting is to enable the first conductive column to expose at least the first contact surface that faces the top surface of the substrate. Then, for the integrated package structure obtained after the first cutting, a shielding layer is formed outside the chip, and the shielding layer is connected to the first conductive column through the first contact surface. An objective of forming the shielding layer herein is to form the fully sealed electromagnetic shielding cavity. Finally, second cutting is performed on the integrated package structure. An objective of the second cutting is to completely divide the plurality of chip package structures that is connected as a whole without losing the first contact surface, so as to obtain a plurality of independent chip package structures.

In a possible implementation of the second aspect, performing first cutting on the integrated package structure includes performing the first cutting on the integrated package structure along a first preset cutting path. The first preset cutting path intersects an area in which a cross section of the first conductive column is located, and a depth of the first preset cutting path is greater than a distance between the top surface of the substrate and a first end face of the first conductive column, and is less than a distance between the top surface of the substrate and a second end face of the first conductive column, the first end face is an end face that is of the first conductive column and that is close to the top surface of the substrate, and the second end face is an end face that is of the first conductive column and that is away from the top surface of the substrate. In this way, the first cutting may enable the first conductive column to expose at least the foregoing first contact surface.

In a possible implementation of the second aspect, performing second cutting on the integrated package structure includes performing the second cutting on the integrated package structure along a second preset cutting path. The first preset cutting path and the second preset cutting path that are located between two adjacent substrates have a same symmetry axis in a direction parallel to a cutting path edge, in this example, a symmetry axis between two side edges of the first preset cutting path is the same as a symmetry axis between two side edges of the second preset cutting path, and a width of the first preset cutting path is greater than a width of the second preset cutting path. In this way, after the second cutting, the first contact surface is not lost, and the plurality of chip package structures that is connected as a whole can be completely divided, so as to obtain the plurality of independent chip package structures.

In a possible implementation of the second aspect, the contact surface exposed by the first conductive column further includes a second contact surface that faces the outer side of the substrate, and a corner is formed between the second contact surface and the first contact surface, and that for the integrated package structure obtained after the first cutting, a shielding layer is formed outside the chip, and the shielding layer is connected to the first conductive column through the first contact surface includes connecting the shielding layer to the first conductive column through the first contact surface and the second contact surface.

In a possible implementation of the second aspect, an edge of the first preset cutting path intersects the area in which the cross section of the first conductive column is located. It should be noted herein that, there may be two cases in which the first preset cutting path intersects the cross-sectional area of the first conductive column. In one case, the edge of the first preset cutting path does not intersect the cross-sectional area of the first conductive column. This case may be understood as that the first conductive column is completely included in the first cutting path. In this way, the first conductive column can expose one end face that faces the top surface of the substrate. In the second case, the edge of the first preset cutting path intersects the cross-sectional area of the first conductive column. This case may be understood as that the first conductive column is not completely included in the first preset cutting path. In this way, the first conductive column can expose one surface that faces the top surface of the substrate and one surface that faces the first preset cutting path, and the two surfaces are connected to each other, so that a corner is formed.

In a possible implementation of the second aspect, the metal layers through which the first conductive column runs are all located inside the substrate, and the substrate further includes a second conductive column, where a metal layer on a bottom surface of the substrate is connected, through the second conductive column, to any one of the metal layers through which the first conductive column runs. In a direction parallel to the top surface of the substrate, a distance between the second conductive column and an edge that is of a side of the first preset cutting path and that is close to the second conductive column is greater than a third distance.

In a possible implementation of the second aspect, a molding is disposed on the top surface of the substrate, and the chip is wrapped in the molding, and that for the integrated package structure obtained after the first cutting, a shielding layer is formed outside the chip includes forming the shielding layer on an upper surface of the molding and a cut surface that is generated through the first cutting, where the cut surface includes the first contact surface, an outer side surface exposed by the molding, and an outer side surface that is exposed by the substrate and that is located between the first contact surface and the top surface of the substrate.

Considering that in an actual cutting process, the dicing blade may shift, the shift of the dicing blade means a shift of a cutting path, and/or a position of an edge of the cutting path changes. For the integrated package structure provided in this embodiment, during the first cutting, impact directly generated by the shift of the dicing blade is that the first preset cutting path does not intersect the first conductive column, or the edge of the first preset cutting path does not intersect the area in which the cross section of the first conductive column is located. In this case, two cases may occur. In one case, the first conductive column is not cut at all. As a result, after the cutting is completed, the first conductive column does not expose any surface. In the second case, the first conductive column is cut to expose a complete end face of the first conductive column, but no corner is formed, and no corner is formed after the second cutting.

Therefore, to ensure that the actual first preset cutting path still intersects the first conductive column after the dicing blade shifts, or ensure that the edge of the first preset cutting path still intersects the area in which the cross section of the first conductive column is located, in a possible implementation of the second aspect, for any substrate in the integrated package structure, a plurality of first conductive columns disposed on a first side of the substrate is distributed on a first straight line parallel to a boundary line of the first side, or distances between the first straight line and the plurality of first conductive columns disposed on the first side of the substrate are within a preset distance range, and the first side is any side of the substrate. In other words, in the integrated package structure, for a single-piece package structure, a plurality of first conductive columns located on a same side of the substrate of the integrated package structure may not be completely located on a same straight line, or in other words, these first conductive columns may be disposed in a staggered manner relative to a straight line, and a distance between each first conductive column and the straight line is less than a distance threshold, in this example, these first conductive columns are distributed in a specified area range. In this case, even if the dicing blade shifts within the area range, it can be ensured that some of the first conductive columns are cut.

For features and technical effects of the chip package structure obtained based on any one of the foregoing manufacturing methods, refer to the technical effects brought by different design manners in the first aspect. Details are not described herein again.

According to a third aspect, an embodiment provides a method for manufacturing a chip package structure, where the method includes:

First, an integrated substrate is prepared. It should be understood that the integrated substrate herein is the substrate of the integrated package structure mentioned in the second aspect, and the integrated substrate may be cut into a plurality of substrates. The integrated substrate includes a plurality of groups of first conductive columns and a plurality of stacked metal layers, the first conductive column runs through at least two metal layers, and a top surface of the integrated substrate includes a plurality of chip mounting areas enclosed by mapping positions of the groups of first conductive columns on the top surface of the integrated substrate, then a chip is mounted in each chip mounting area on the top surface of the integrated substrate, then a molding is formed on the top surface of the integrated substrate by using a plastic package material, so that the chip is wrapped by the plastic package material, to obtain an integrated package structure, then first cutting is performed on the integrated package structure, so that each group of first conductive columns expose a first contact surface that faces the top surface. Next, a shielding layer is formed on an upper surface of the molding and a cut surface that is generated through the first cutting, where the cut surface includes the first contact surface, and finally, second cutting is performed on the integrated package structure to obtain a plurality of chip package structures through separation, where a shielding layer on each chip package structure is connected to the first conductive column through the first contact surface, and the first conductive column is configured to ground the shielding layer.

In a possible implementation of the third aspect, that an integrated substrate is prepared includes: First, a core plate is prepared by using an insulation material; then, on one side of the core plate, the plurality of first metal layers is formed, and the plurality of groups of first conductive columns that run through the at least two first metal layers is formed, where the plurality of first metal layers is stacked in a direction perpendicular to the top surface of the substrate and is separated through a first insulation layer; and a plurality of groups of second metal layers is formed on the other side of the core plate, where different groups of second metal layers are stacked in the direction perpendicular to the top surface of the substrate, and are separated through a second insulation layer; a plurality of second metal layers in a same group of second metal layers is formed in a plurality of preset areas on a same surface, and a distance between an edge of the second metal layer in any preset area and an edge of the preset area is greater than a fourth distance; and the second insulation layer has a protruding part extending in a direction perpendicular to the surface, and the second metal layers on the same surface are separated through the protruding part; and the surface herein includes a surface on the other side of the core plate and a surface that is of the second insulation layer and that is away from the core plate, that is, a surface used for forming the second metal layers, and the plurality of preset areas on the surface are respectively areas enclosed by the mapping positions of the groups of first conductive columns on the surface.

In a possible implementation of the third aspect, one group of first conductive columns include a plurality of parts, and mapping positions of the parts of the first conductive columns on the top surface are located on all sides of the chip mounting area, where mapping positions of a first part of the first conductive columns on the top surface are distributed on a straight line or distances between the straight line and the mapping positions are within a preset distance range, and the first part is any one of the plurality of parts.

In a possible implementation of the third aspect, that an integrated substrate is prepared further includes, a plurality of groups of second conductive columns is formed, where mapping positions of a same group of second conductive columns on the surface (namely, a surface on which a group of second metal layers are formed) are located in a same preset area, where the second conductive column runs through a plurality of second metal layers, and connects at least one first metal layer through which the first conductive column runs to a metal layer located on a bottom surface of the substrate.

In a possible implementation of the third aspect, distances between an edge of the preset area and the mapping positions of the second conductive columns in the preset area are greater than a fifth distance.

According to a fourth aspect, an embodiment provides an electronic device, including a mainboard and the chip package structure described in the foregoing embodiments. The mainboard is located on a surface that is of the substrate and that is on a side away from the chip in the chip package structure, and is connected to the chip package structure. Because the chip package structure in the electronic device in this embodiment is the same as the chip package structures in the foregoing embodiments, the two chip package structures can resolve same technical problems and obtain same technical effects. Details are not described herein again.

For technical effects brought by any design manner of the second aspect to the fourth aspects, refer to technical effects brought by different design manners of the first aspect, and details are not described herein again.

### BRIEF DESCRIPTION OF DRAWINGS

FIG. 1 is a diagram of a structure of an electronic device according to an embodiment;

FIG. 2 is an exploded view of an electronic device according to an embodiment;

FIG. 3 is a diagram of a structure of a mainboard assembly in an electronic device according to an embodiment;

FIG. 4 is a diagram of a structure of a chip package structure in an electronic device according to an embodiment;

FIG. 5A is a diagram of a top surface of an integrated package structure;

FIG. 5B is a cross-sectional view of the integrated package structure shown in FIG. 5A based on a cutting direction and a cross-sectional line M1-N1;

FIG. 6 is a diagram of a chip package structure;

FIG. 7A is a diagram of a top surface of an integrated package structure according to an embodiment;

FIG. 7B is a cross-sectional view of the integrated package structure shown in FIG. 7A based on a cutting direction and a cross-sectional line M2-N2;

FIG. 8 is a cross-sectional view of another integrated package structure according to an embodiment;

FIG. 9 is a cross-sectional view of still another integrated package structure according to an embodiment;

FIG. 10 is a diagram of a metal layer being a metal wiring layer according to an embodiment;

FIG. 11A and FIG. 11B are diagrams of cutting paths in a method for manufacturing a chip package structure according to an embodiment with reference to FIG. 7A and FIG. 7B;

FIG. 12 is a diagram of an integrated package structure obtained after first cutting is performed on the integrated package structure shown in FIG. 7A and FIG. 7B by using a method for manufacturing a package structure according to an embodiment;

FIG. 13 is a diagram of a surface exposed by a first conductive column after first cutting;

FIG. 14 is a diagram of an integrated package structure obtained after a shielding layer is formed on an integrated package structure shown in FIG. 13 by using a method for manufacturing a package structure according to an embodiment;

FIG. 15 is a diagram of a chip package structure obtained after second cutting is performed on the integrated package structure shown in FIG. 14 by using a method for manufacturing a package structure according to an embodiment;

FIG. 16 is a diagram of an integrated package structure obtained after first cutting is performed on the integrated package structure shown in FIG. 8 by using a method for manufacturing a package structure according to an embodiment;

FIG. 17 is a diagram of an integrated package structure obtained after a shielding layer is formed on the integrated package structure shown in FIG. 16 by using a method for manufacturing a package structure according to an embodiment;

FIG. 18 is a diagram of a chip package structure obtained after second cutting is performed on the integrated package structure shown in FIG. 17 by using a method for manufacturing a package structure according to an embodiment;

FIG. 19 is a diagram of an integrated package structure obtained after first cutting is performed on the integrated package structure shown in FIG. 9 by using a method for manufacturing a package structure according to an embodiment;

FIG. 20 is a diagram of an integrated package structure obtained after a shielding layer is formed on the integrated package structure shown in FIG. 19 by using a method for manufacturing a package structure according to an embodiment;

FIG. 21 is a diagram of a chip package structure obtained after second cutting is performed on the integrated package structure shown in FIG. 20 by using a method for manufacturing a package structure according to an embodiment;

FIG. 22 is a diagram of a cutting scenario in which a dicing blade shifts according to an embodiment;

FIG. 23 is a diagram of a distribution manner of first conductive columns according to an embodiment; and

FIG. 24 is a flowchart of a method for manufacturing a chip package structure according to an embodiment.

### DESCRIPTION OF EMBODIMENTS

The following describes the technical solutions in embodiments of this disclosure with reference to the accompanying drawings in embodiments. It is clear that the described embodiments are merely some rather than all of embodiments of this disclosure.

Hereinafter, the terms “first”, “second”, and the like are used only for descriptive purposes, to distinguish between same items or similar items with basically same functions and actions, and cannot be understood as indicating or implying relative importance or implicitly indicating a quantity of indicated technical features. Therefore, a feature limited by “first”, “second”, or the like may explicitly or implicitly include one or more features.

In addition, in the descriptions of embodiments, “a plurality of” means two or more than two unless otherwise specified.

In addition, orientation terms such as “up”, “down”, “left”, “right”, “horizontal”, “top surface”, “top”, “bottom surface”, “bottom”, “side surface”, “vertical”, “outside”, “outer side”, and “inside” are defined relative to orientations of schematic placement of complements in the accompanying drawings. It should be understood that, these directional terms are relative concepts. They are intended to provide relative description and clarification and may vary correspondingly based on changes of the orientations in which the components in the accompanying drawings are placed.

It should be specially noted that most descriptions relate to a substrate. For ease of description, a surface that is of the substrate and that is used to dispose a chip is referred to as a “top surface” of the substrate, a surface that is of the substrate and that is opposite to the “top surface” of the substrate, that is, a surface that is of the substrate and that is used to connect to a mainboard of an electronic device, is referred to as a “bottom surface”, and other surfaces of the substrate are “side surfaces” of the substrate. For ease of understanding and description, a space rectangular coordinate system is established in some accompanying drawings. A “top surface” and a “bottom surface” in embodiments may be described as a surface parallel to an X-Y surface shown in the accompanying drawings, and a “side surface” is a surface perpendicular to the X-Y surface, for example, a surface parallel to the X-Y surface or a surface parallel to the X-Y surface.

Unless otherwise clearly specified and limited, the term “connection” should be understood in a broad sense. For example, a “connection” may be a mechanical connection, and the mechanical connection may be a fixed connection, a detachable connection, or an integral connection; or may be an electrical connection, or may be a communication connection. The connection may be a direct connection, or a connection through an intermediate medium.

In addition, in embodiments of this disclosure, terms such as “example” or “for example” are used to represent giving an example, an illustration, or a description. Any embodiment or design scheme described as an “example” or “for example” in embodiments should not be explained as being more preferred or having more advantages than another embodiment or design scheme. Exactly, use of the terms such as “example” or “for example” is intended to present a related concept in a specific manner for ease of understanding.

SIP is widely used in technical fields of information and communication technologies (ICT), such as computer industry, communication networks, consumer electronics, space industry, and automobile industry.

An objective of embodiments of this disclosure is to provide a chip package structure and a method for manufacturing the chip package structure (briefly referred to as a manufacturing method below). The chip package structure may be a standard SIP product, or may be referred to as a SIP standard component. The chip package structure may be integrated in an electronic device, to implement a plurality of functions of the electronic device.

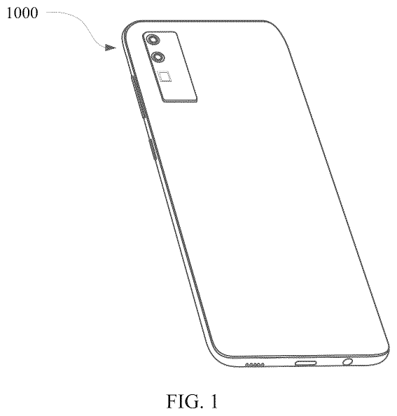

In other words, an embodiment further provides an electronic device including the chip package structure. The electronic device may be an electronic device in the field of ICT technologies, such as a server, an optical communication device, a mobile phone, a tablet personal computer, a laptop computer, a personal digital assistant (PDA), a camera, a personal computer, a notebook computer, a vehicle-mounted device, a wearable device, augmented reality (AR) glasses, an AR helmet, virtual reality (VR) glasses, a VR helmet, or other devices that need to process/store/receive and send data. A specific form of the electronic device is not specifically limited in this embodiment. For ease of description, the following is all described by using an example in which the electronic device is a mobile phone shown in FIG. 1.

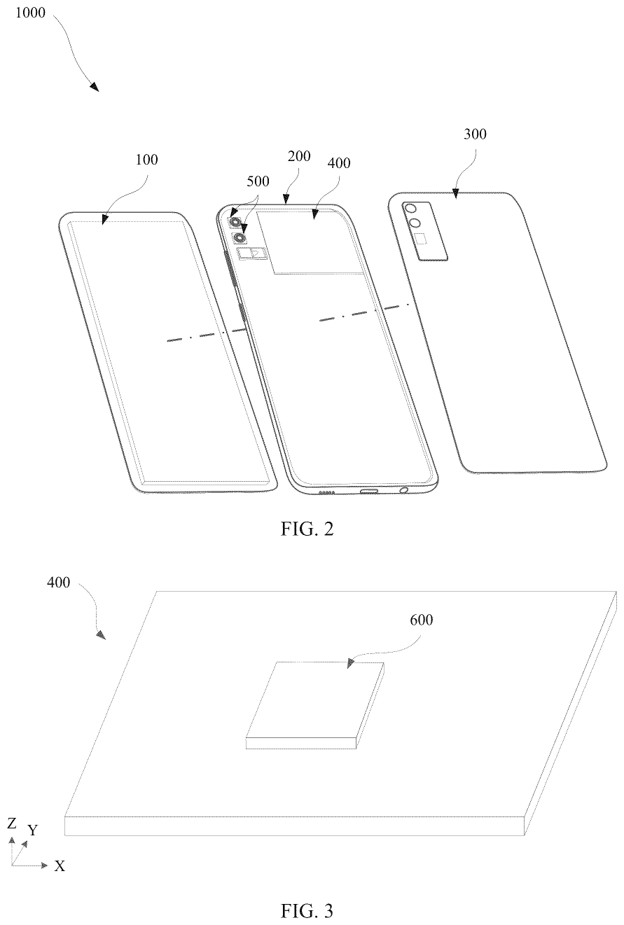

FIG. 1 is a three-dimensional diagram of an electronic device according to some embodiments, and FIG. 2 is an exploded view of the electronic device shown in FIG. 1. With reference to FIG. 1 and FIG. 2, an electronic device 1000 is a mobile phone. The electronic device 1000 may include a screen 100, a middle frame 200, a rear housing 300, and a mainboard 400 that is fastened to the middle frame 200, as shown in FIG. 1.

It may be understood that FIG. 1 and FIG. 2 only schematically show some components included in the electronic device 1000. Actual shapes, actual sizes, actual positions, and actual structures of these components are not limited by FIG. 1 and FIG. 2. For example, in some other examples, the electronic device 1000 may alternatively not include the screen 100. Alternatively, the electronic device 1000 may further include a camera 500 shown in FIG. 2.

In this embodiment, the electronic device 1000 further includes a chip package structure 600 shown in FIG. 3. The chip package structure 600 is disposed on the mainboard 400, and is connected to the mainboard 400. For example, the chip package structure 600 may be connected to the mainboard 400 through a ball grid array (BGA) or a plurality of copper pillar bumps (CPB) arranged in an array, so that the chip package structure 600 can implement signal transmission with other components or a component stacking structure on the mainboard 400.

It should be noted that the mainboard 400 may be a PCB. There may be one, two, or more chip package structures 600 on the mainboard 400. This is not limited.

For ease of the following description, some accompanying drawings in embodiments show a three-dimensional space coordinate system, namely, an X, Y, and Z coordinate system. With reference to FIG. 3, a plane in which the mainboard 400 is located is an XY plane. For example, the mainboard 400 shown in FIG. 3 is rectangular. An X-axis may be a length direction of the mainboard 400, and may also be a left-right direction. A Y-axis may be a width direction of the mainboard 400. A Z-axis is a direction perpendicular to or approximately perpendicular to the mainboard 400 within a manufacturing tolerance range. Still using the mainboard 400 shown in FIG. 3 as an example, two surfaces of the mainboard 400 along the Z-axis may be a bottom surface and a top surface of the mainboard 400 respectively, and two surfaces of the mainboard 400 along the X-axis and two surfaces of the mainboard 400 along the Y-axis may be four side surfaces of the mainboard 400. The chip package structure 600 is disposed on a top surface of the mainboard 400.

The foregoing description is provided by using an example in which the mainboard 400 is a cuboid. The mainboard 400 may alternatively be in a shape such as a square or a polygon. The shape of the mainboard 400 is not limited in this embodiment of this disclosure.

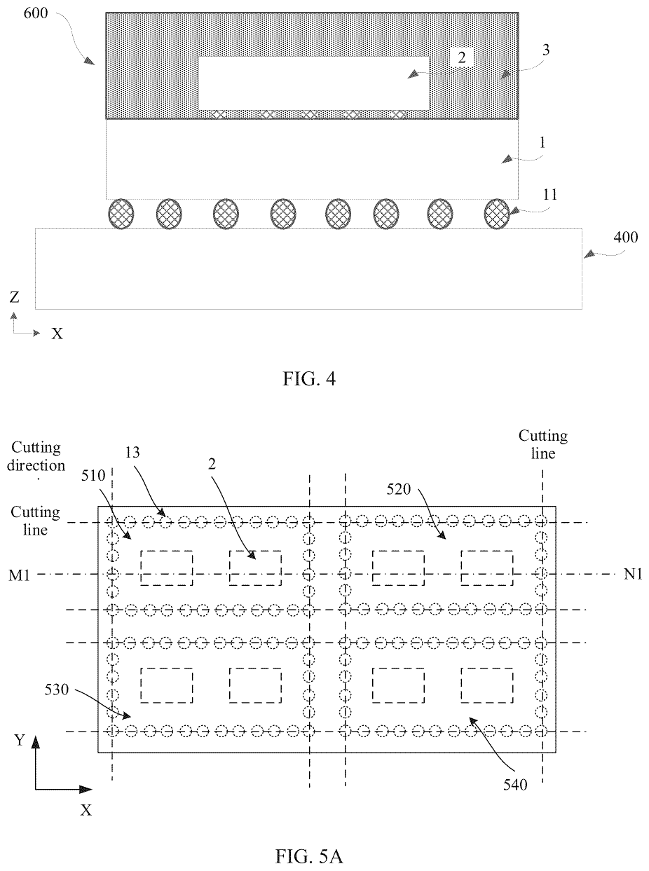

The following describes a structure of the chip package structure 600. With reference to FIG. 4, the chip package structure 600 may include a substrate (SUB) 1, a chip 2 disposed on the substrate 1, and a molding 3 that wraps the chip 2. The molding 3 herein may also be referred to as a plastic package structure. When applied to a chip package process, the substrate 1 is configured to carry a chip or a chip stacking structure, to form the chip package structure 600. High-density interconnection lines are disposed on a top surface, a bottom surface, and inside of the substrate 1, and are configured to implement connections between different chips 2 or between the chip 2 and the mainboard 400. The interconnection line may be a metal layer, for example, a copper layer or a patterned interconnection line/circuit structure, or may be a wiring layer and/or a re-wiring layer. In the example shown in FIG. 4, two surfaces of the substrate 1 in the Z-axis direction are a bottom surface and a top surface of the substrate 1 respectively, and the chip 2 is disposed on the top surface of the substrate 1. A ball grid array 11 is disposed on the bottom surface of the substrate 1, and is configured to implement connections between the interconnection lines in the substrate and the mainboard 400. There may be one or more chips 2 in the chip package structure 600. This is not limited.

The chip 2 may be a processing chip having a data processing function, for example, a chip that can process data, such as a central processing unit (CPU), a system on chip (SOC), or a graphics processing unit (GPU). The foregoing memory may be a random-access memory (RAM), or may be a read-only memory (ROM).

The chip may include an active electronic component, a passive electronic component, and a component such as a MEMS component or an optical component, for example, a circuit component such as a diode, a resistor, a resistor network, a capacitor, an inductor, a transformer, a relay, or a switch, an analog integrated circuit component that integrates an operation amplifier, a comparator, logarithmic and exponential amplifiers, an analog multiplier/divider, an analog switch, a wave-form generator, a power amplifier, and the like, or a digital integrated circuit component such as a logic gate circuit, a flip-flop, a register, a decoder, a data comparator, a driver, a counter, a shaping circuit, a programmable logic device (PLD), a microprocessor (MPU), a microcontroller (MCU), a digital signal processor (DSP), or the like.

An electromagnetic sensitive component or an electromagnetic interference source may exist inside the chip package structure 600. Therefore, to protect the electromagnetic sensitive component inside the chip package structure 600 from interference and reduce interference from the interference source inside the chip package structure 600 to an external electronic component, in a related technology, an electromagnetic shielding material film layer (a shielding layer for short) is formed on an outer surface of the chip package structure 600, to form an electromagnetic shielding cavity, and all electronic components in the chip package structure 600 are sealed in the electromagnetic shielding cavity. In this way, electromagnetic radiation generated inside the chip package structure 600 and external electromagnetic waves can be shielded, so as to reduce interference to the electronic components inside the chip package structure 600. The electromagnetic shielding function implemented by using the foregoing electromagnetic shielding cavity is an electromagnetic self-shielding function of the chip package structure 600.

An integrated package structure can include hundreds of integrally formed single-piece package structures. A manufacturing process of the chip package structure 600 may include a step of cutting the integrated package structure, to obtain the single-piece package structures in the integrated package structure by cutting, and then a shielding layer is manufactured for each single-piece package structure, to form the electromagnetic shielding cavity.

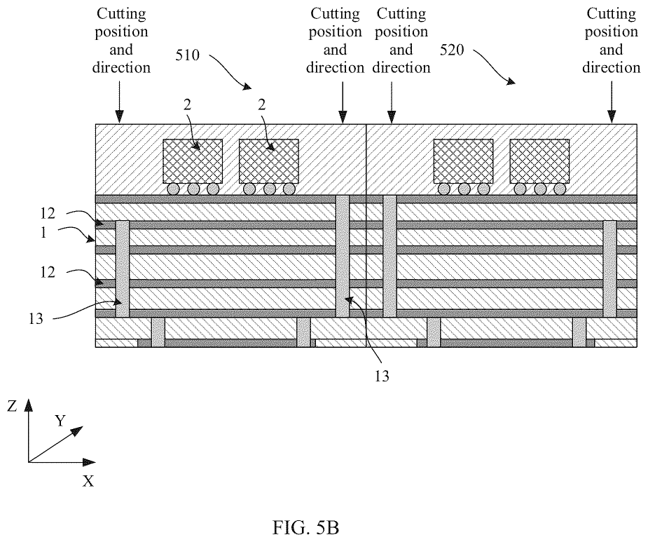

FIG. 5A is a diagram of a top surface (X-Y plane) of a to-be-cut integrated package structure. FIG. 5B is a cross-sectional view of the top surface of the integrated package structure based on a cutting direction and a cross-sectional line M1-N1. As shown in FIG. 5A and FIG. 5B, the integrated package structure includes four integrally formed single-piece package structures, that is, a package structure 510, a package structure 520, a package structure 530, and a package structure 540. Based on the cutting line and the cutting direction that are shown, the four one-piece package structures of the integrated package structure can be obtained by cutting. It should be understood that the cutting line herein is a line-shaped mark that indicates a cutting position or an edge position of a cutting path, rather than a line-shaped cutting tool. The cutting path is located between two adjacent single-piece package structures, and may be understood as a path that has a width and depth and that is generated when a cutting tool is used to perform cutting at a position indicated by a cutting line. The width of the cutting path is a size of the cutting path in the X-axis direction, and the depth of the cutting path is a size of the cutting path in the Y-axis direction. Because the four one-piece package structures are completely the same, the package structure 510 is used as an example to describe a feature of the integrated package structure. It can be learned that, in the package structure 510, the substrate 1 includes a plurality of stacked metal layers 12. One of the plurality of metal layers 12 is formed on the top surface of the substrate 1, one is formed on the bottom surface of the substrate 1, and others are formed inside the substrate 1. Except the metal layer formed on the bottom surface, the remaining metal layers 12 all extend outward to peripheral edges of the substrate 1, or in other words, all extend to cutting positions. Still with reference to FIG. 5A and FIG. 5B, the substrate 1 further includes conductive columns 13, and the conductive columns 13 run through the plurality of metal layers 12.

It should be understood that substrates of the plurality of single-piece package structures are integrally formed to form an integrated substrate. The integrated substrate herein is a substrate of the integrated package structure.

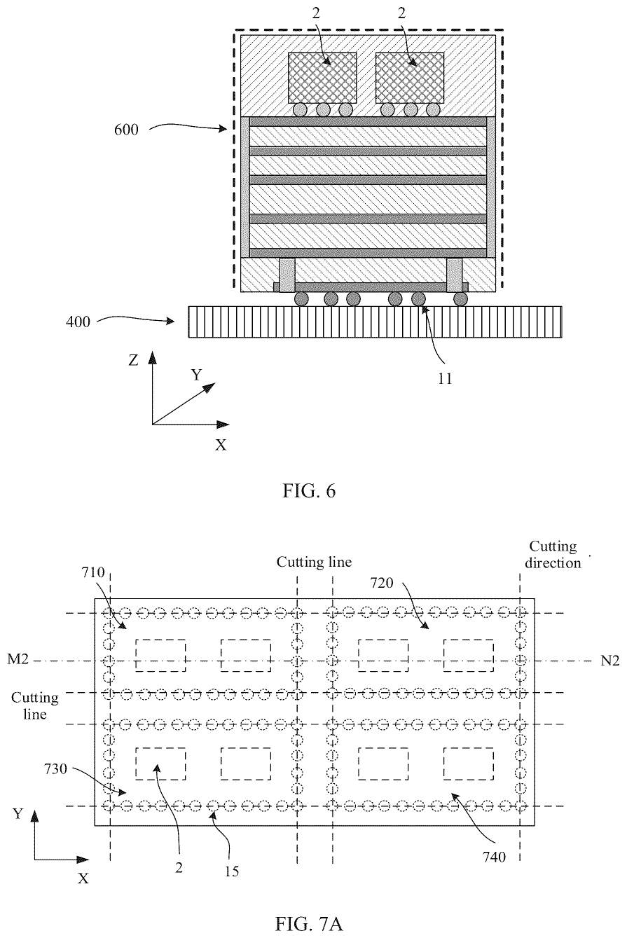

For the foregoing integrated package structure, generally, according to the predetermined cutting positions shown in FIG. 5A and FIG. 5B, the integrated package structure is first cut to a bottom surface of the integrated package structure at a time down from the top surface of the integrated package structure, so as to completely separate the plurality of one-piece package structures (for example, the package structure 510/520/530/540) that are connected as a whole. Then, a shielding layer is formed outside each single-piece package structure, so as to obtain the chip package structure having a self-shielding function shown in FIG. 6.

It can be learned from FIG. 6 that, cutting enables the conductive column 13 to expose a surface, and the shielding layer (as shown by a dashed line in FIG. 6) is connected to the conductive column 13 through the surface. Because the conductive column 13 is connected to a grounding circuit on the bottom surface of the substrate, the grounding circuit on the bottom surface of the substrate may be used to connect to a grounding circuit in the mainboard 400, to finally implement grounding, thereby obtaining a fully sealed electromagnetic shielding cavity.

However, the examples shown in FIG. 5A, FIG. 5B, and FIG. 6 have the following disadvantages.

Disadvantage 1: A position of the cutting line causes a plurality of metal layers below the cutting line, and during cutting, the integrated package structure is cut from the top surface of the integrated package structure to the bottom surface of the integrated package structure. Therefore, it means that all the metal layers 12 in the substrate 1 are cut. It is easily understood that, because the hardness of the metal layer is greater than that of the substrate material, a larger quantity of metal layers 12 that are cut indicates larger abrasion caused to the dicing blade (for example, a saw blade), and costs are high.

Disadvantage 2: In an actual cutting process, the dicing blade (which may alternatively be laser) may probably shift in a left/right direction (the X-axis direction in FIG. 5A). As a result, an actual cutting position is slightly different from an expected cutting position in a process design. Once the dicing blade shifts, the conductive column 13 may be cut off as a whole, or the conductive column 13 is not cut at all. No matter which case occurs, the shielding layer cannot be connected to the metal layer on the bottom surface of the substrate, and therefore cannot be grounded. As a result, the electromagnetic shielding function cannot be implemented.

Disadvantage 3: After the cutting is completed, for each single-piece package structure, a shielding layer needs to be formed on a side surface of each single-piece package structure. Therefore, positions of the plurality of single-piece chip package structures need to be arranged (layout), that is, the plurality of single-piece chip package structures is placed at intervals at positions that facilitate preparation of the shielding layer. The layout process increases the complexity of the overall manufacturing process.

Disadvantage 4: The shielding layer is connected to the conductive column 13 by contacting the side surface exposed by the conductive column 13. Based on a process for forming the shielding layer, for example, a sputtering process, because the shielding layer that can be formed on the side surface is thin, reliability of contact between the shielding layer and the conductive column 13 is poor, and the shielding layer and the conductive column 13 are in contact with a resistor, resulting in poor shielding effect.

Disadvantage 5: Because the shielding layer is generally formed on the upper surface and the side surface of the chip package structure by using a film forming process such as sputtering, spraying, and electroplating, the electromagnetic shielding material is easily splashed onto a solder ball 11 (or a pad) on the bottom surface of the substrate 1. To prevent the electromagnetic shielding material from being splashed onto the solder ball 11 on the bottom surface of the substrate 1, a distance between the solder ball 11 and the peripheral edge of the substrate 1 is required to be sufficiently long, which is usually 150 micrometers (μm). In some scenarios, a chip package size needs to be increased to meet this requirement. This is contrary to a requirement of the electronic device for miniaturization of the chip package structure.

Disadvantage 6: Because the shielding layer covers an outermost area of the substrate, the shielding layer is extremely prone to fall-off due to factors such as collision/vibration.

Embodiments of this disclosure provide a chip package structure and a manufacturing method therefor. In each implementable design of the chip package structure and the manufacturing method therefor, at least one of the foregoing disadvantages can be eliminated, or a plurality of the foregoing disadvantages can be eliminated at the same time. In other words, the chip package structure provided in embodiments has a reliable electromagnetic self-shielding function. In this way, when the chip package structure is used in an electronic device, electronic components of the chip package structure can effectively reduce electromagnetic interference, and can also reduce interference from the electronic device to other electronic components.

It should be noted that the chip package structure provided in embodiments is a standard chip package structure obtained by processing the integrated package structure provided by using the manufacturing method provided in this disclosure. The following first describes the integrated package structure and the manufacturing method, so that a reader can understand an inventive concept of this disclosure based on a causal relationship between the manufacturing method and a product obtained.

First, the integrated package structure provided in embodiments of this disclosure is described.

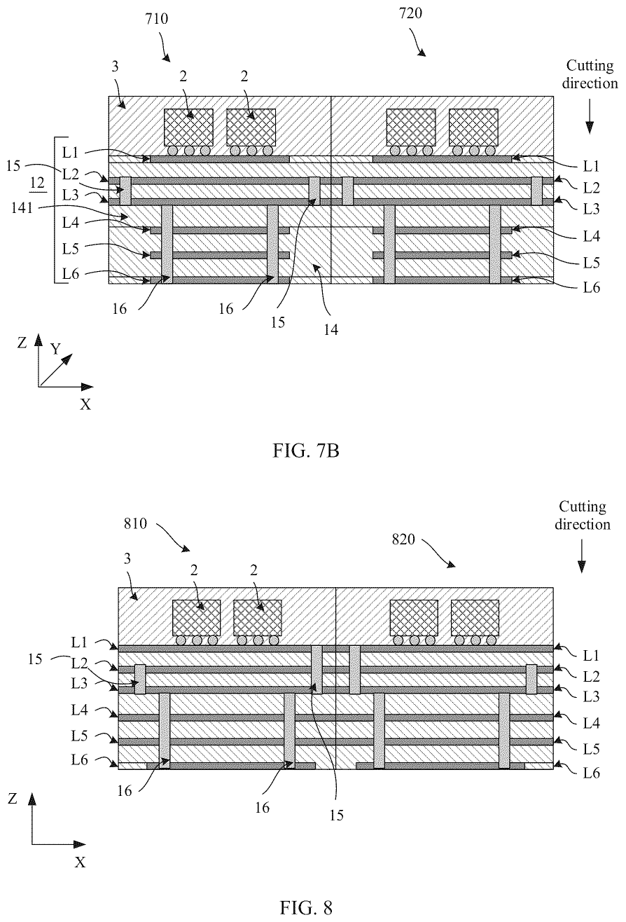

FIG. 7A is a diagram of a top surface (X-Y plane) of a to-be-cut integrated package structure. FIG. 7B is a cross-sectional view of the top surface of the integrated package structure based on a cutting direction and a cross-sectional line M2-N2.

As shown in FIG. 7A and FIG. 7B, based on the cutting line and the cutting direction that are shown, the integrated package structure may be divided into four one-piece package structures through simulation, that is, a package structure 710, a package structure 720, a package structure 730, and a package structure 740. In this example, the integrated package structure includes four integrally formed one-piece package structures, and structures of the four one-piece package structures are completely the same. In another example, the integrated package structure may include more integrally formed single-piece package structures, and structures of different single-piece package structures may be different. This is not limited in this disclosure. For ease of description, in the following embodiments, when an integrated package structure of any design is described, one of the single-piece package structures is used as an example for description.

Using the package structure 710 as an example, the package structure 710 includes the substrate 1 (a reference numeral of the substrate 1 is not shown in FIG. 7B) and the chip 2 mounted on the top surface of the substrate 1, where the chip 2 is wrapped in the molding 3. The substrate 1 includes a plurality of insulation layers 14 made of insulation materials (substrate panel materials such as polypropylene and ceramic) and a plurality of metal layers 12, and the plurality of metal layers 12 is respectively L1, L2, L3, L4, L5, and L6 that are shown in the figure. The plurality of metal layers 12 is stacked in a direction (that is, the Z-axis direction) perpendicular to the top surface of the substrate 1 (the bottom surface of the substrate 1), and two adjacent metal layers 12 are separated through the insulation layer 14. L1 is formed on the top surface of the substrate 1, L2, L3, L3, L4, and L5 are formed inside the substrate 1, and L6 is formed on the bottom surface of the substrate 1.

It should be noted that, in the integrated package structure, for any two adjacent single-piece package structures, such as the package structure 710 and the package structure 720, or the package structure 710 and the package structure 730, metal layers 12 that are disposed at a same layer may be integrally formed, or may be separated. For example, a metal layer L2 in the package structure 710 and a metal layer L2 in the package structure 720 are integrally formed, that is, there is no spacing between the two metal layers L2; and a metal layer L4 in the package structure 710 and a metal layer L4 in the package structure 720 are not integrally formed, that is, the two metal layers L4 are separated through an insulation material.

Alternatively, it may be understood that, for a single-piece package structure such as the package structure 710, some of the metal layers 12 of the package structure extend outward to a cutting path indicated by the cutting line and the cutting direction. The other metal layers 12 extend outward to positions that do not reach an edge D of the cutting path. An objective of such a design is to ensure that no all the metal layers 12 are cut during the cutting. For example, only metal layers that extend to the cutting path are cut, and metal layers that do not extend are not cut. In addition, it may be further ensured that in the obtained chip package structure, some of the metal layers 12 are still wrapped in the insulation material. For ease of description, in this embodiment, a metal layer that extends to the cutting path is referred to as a first-type metal layer (or referred to as a first metal layer), and a metal layer that does not extend to the cutting path is referred to as a second-type metal layer (or referred to as a second metal layer).

Still with reference to the package structure 710 in FIG. 7B, the substrate 1 of the package structure 710 further includes a plurality of first conductive columns 15, and the plurality of first conductive columns 15 is distributed on four sides of the substrate 1. In addition, the first conductive column 15 runs through at least two first-type metal layers. In the example shown in FIG. 7B, the first conductive column 15 runs through metal layers L2 and L3. Certainly, the first conductive column 15 may alternatively be connected to two different first-type metal layers through two ends of the first conductive column 15, and does not run through the two first-type metal layers. In addition, in the package structure 710 shown in FIG. 7B, the substrate 1 of the package structure 710 further includes a plurality of second conductive columns 16, the second conductive column 16 is located on a side that is of the first conductive column 15 and that is away from a cutting position (the cutting path), and a distance between axes of the second conductive column 16 and the first conductive column 15 is greater than a sum of radiuses of the second conductive column 16 and the first conductive column 15. In other words, the second conductive column 16 is disposed close to the inside of the substrate relative to the first conductive column 15. At least one of the plurality of metal layers 12 through which the first conductive column 15 runs is connected to the metal layer on the bottom surface of the substrate through the second conductive column 16. In addition, the second conductive column 16 further runs through a plurality of second-type metal layers. For example, in the package structure 710 shown in FIG. 7B, one end of the second conductive column 16 is connected to L3, and the other end is connected to L6 in a form of running through L6. In addition, the second conductive column 16 further runs through both L4 and L5.

It can be learned that, in the integrated package structure, the second conductive column 16 has two functions, one is to connect one of the metal layers 12 through which the first conductive column 15 runs to the metal layer 12 on the bottom surface of the substrate 1, and the other is to implement electrical interconnections between the plurality of second-type metal layers through which the second conductive column 16 runs. In addition, a position at which the second conductive column 16 is disposed can ensure that the second conductive column 16 is still wrapped in the insulation material after the metal layers 12 are cut.

In the foregoing package structure 710, in a direction parallel to the top surface of the substrate, a distance between the second conductive column 16 and a side that is of the first conductive column 15 and that is away from the first cutting path is D1, where D1 is greater than zero. In the direction parallel to the top surface of the substrate, a distance between an edge of the second metal layer and a side that is of the first conductive column and that is away from the first cutting path is D2, where D2 is greater than 0, and D1 is greater than D2. In the direction parallel to the top surface of the substrate, a distance between the second conductive column 16 and an edge that is of a side of the first cutting path and that is close to the second conductive column 16 is D3, where D3 is greater than D1. In the foregoing package structure 710, both the first conductive column 15 and the second conductive column 16 are ground holes filled with metal materials, and the first conductive column 15 is connected to the grounding circuit on the bottom surface of the substrate 1 through the second conductive column 16. The grounding circuit herein is a circuit in the metal layer on the bottom surface of the substrate.

It can be learned from the foregoing that, in the integrated package structure shown in FIG. 7A and FIG. 7B, for the single-piece package structure of the integrated package structure, both the first-type metal layers and the second-type metal layers exist inside the substrate 1 of the single-piece package structure. In addition, each first conductive column 15 runs through a same quantity of metal layers 12, and the metal layers 12 through which the first conductive column 15 runs or connected to the first conductive column 15 are all the foregoing first-type metal layers, and are all formed inside the substrate 1, so that one first-type metal layer needs to be connected to the grounding circuit on the bottom surface of the substrate through the second conductive column 16.

It should be noted that, in some other designs of the integrated package structure in this disclosure, still using a single-piece package structure as an example, the metal layers inside the substrate of the integrated package structure may include and include only first-type metal layers such as L2 and L3, the first conductive column may run through more first-type metal layers, and/or the first conductive columns located on different sides of the substrate may run through different quantities of first-type metal layers. For example, FIG. 8 is a cross-sectional view of an integrated package structure in a cutting direction. In a package structure 810 and a package structure 820, L1, L2, L3, L4, and L5 all extend to the cutting path, that is, are all the first-type metal layers defined above. In the package structure 810, the first conductive column 15 on the left side of the substrate 1 runs through L2 and L3, and the first conductive column 15 on the right side of the substrate 1 runs through L1, L2, and L3. In the package structure 820, the first conductive column 15 on the left side of the substrate 1 runs through L1, L2, and L3, and the first conductive column 15 on the right side of the substrate 1 runs through L2 and L3.

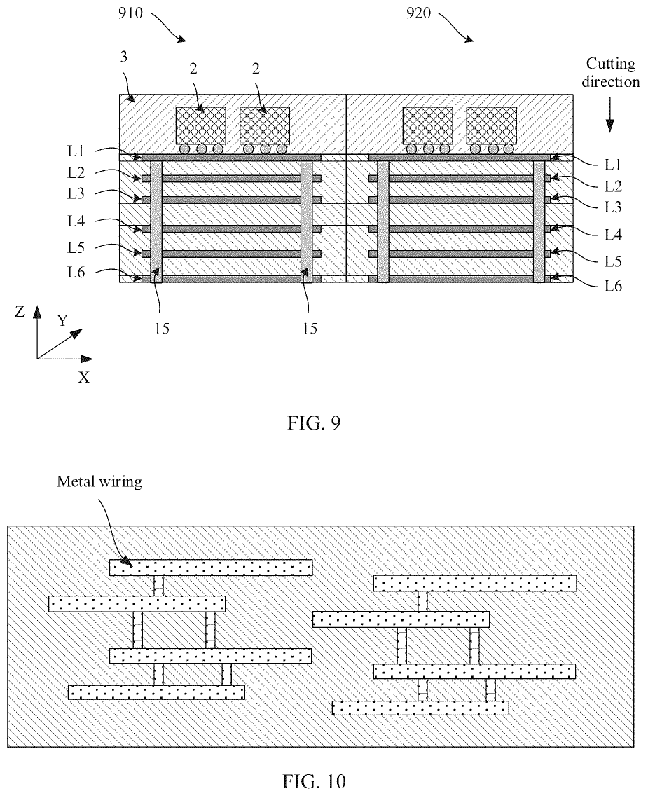

In still some designs of the integrated package structure, the substrate of the single-piece package structure may alternatively include and include only the second-type metal layers such as L4 and L5, and the first conductive column runs through at least two metal layers, and one of the metal layers is formed on the bottom surface of the substrate. For example, FIG. 9 is a cross-sectional view of an integrated package structure in a cutting direction. In a package structure 910 and a package structure 920, none of edges of L1, L3, L3, L4, L5, and L6 extend to the cutting path, that is, are all the second-type metal layers defined above. The first conductive column 15 runs through L1, L3, L3, L4, L5, and L6.

It should be noted that, in the integrated package structure shown in FIG. 7B, one of the plurality of insulation layers 14 is a core plate 141. Both the first-type metal layer and the first conductive column 15 are formed on a side that is of the core plate 141 and that is close to the chip 2. A second-type metal layer is formed on the bottom surface of the substrate 1, and the remaining second-type metal layers and the second conductive column 16 are both formed on the side that is of the core plate 141 and that is away from the chip 2.

It is easily understood that the integrated package structures shown in FIG. 7A to FIG. 9 do not include all possible integrated package structures provided in embodiments of this disclosure. For example, the integrated package structures may further include more or fewer metal layers, and may further include conductive columns whose quantities, functions, and/or positions are different from those in the foregoing examples.

In addition, the metal layer mentioned in the foregoing embodiment may be a metal film layer that completely covers a surface of an insulation structure, or may be a metal wiring layer shown in FIG. 10.

The following describes a method for manufacturing a chip package structure in embodiments of this disclosure with reference to the integrated package structures shown above.

First, the integrated package structure is obtained, for example, the integrated package structures shown in FIG. 7A to FIG. 9.

Second, first cutting is performed on the integrated package structure along the first cutting path. An objective of the first cutting is to enable the first conductive column to expose at least a first contact surface that faces the top surface of the substrate. Alternatively, the first conductive column is enabled to expose the first contact surface that faces the top surface of the substrate and a second contact surface that faces the side surface of the substrate, where a corner may be formed between the second contact surface and the first contact surface, for example, a “right-angle-shaped” corner.

Then, for the integrated package structure obtained after the first cutting, a shielding layer is formed on a top surface of the molding and a cut surface that is formed by the first cutting, and the shielding layer is connected to the first conductive column through a surface (the first contact surface, or the first contact surface and the second contact surface) exposed by the first conductive column. It should be understood that the cut surface formed by the first cutting includes an outer side surface exposed by the molding, the first contact surface, and an outer side surface that is exposed by the substrate between the first contact surface and the top surface of the substrate. Herein, an objective of forming the shielding layer is to form an electromagnetic shielding cavity, and the shielding layer and the first conductive column connected to the shielding layer are both components that form the electromagnetic shielding cavity. After the electromagnetic shielding cavity is formed, all electronic components in the single-piece package structure are wrapped in the electromagnetic shielding cavity. In this way, the shielding layer can implement a function of shielding electromagnetic interference. The first cutting process can ensure that the first conductive column exposes at least one surface, that is, the first contact surface. Therefore, when the shielding layer is formed, it can also be ensured that the shielding layer can be connected to the first conductive column through the first contact surface.

Finally, second cutting is performed, along a second cutting path, on the integrated package structure obtained in the foregoing step, to obtain a plurality of independent chip package structures. An objective of the second cutting is the same as that of the first cutting, that is, to enable the first conductive column to expose at least the first contact surface, or expose the first contact surface and the second contact surface. In other words, the first contact surface exposed by the first conductive column, or the first contact surface and the second contact surface that are exposed by the first conductive column are formed through a combination of processes of the first cutting and the second cutting. Another objective of the second cutting is to completely divide the plurality of chip package structures that is connected as a whole, so as to obtain the plurality of independent chip package structures.

With reference to the integrated package structure shown in FIG. 7B, the following sequentially describes examples of processes of the first cutting, forming the shielding layer, and the second cutting in the foregoing cutting processes.

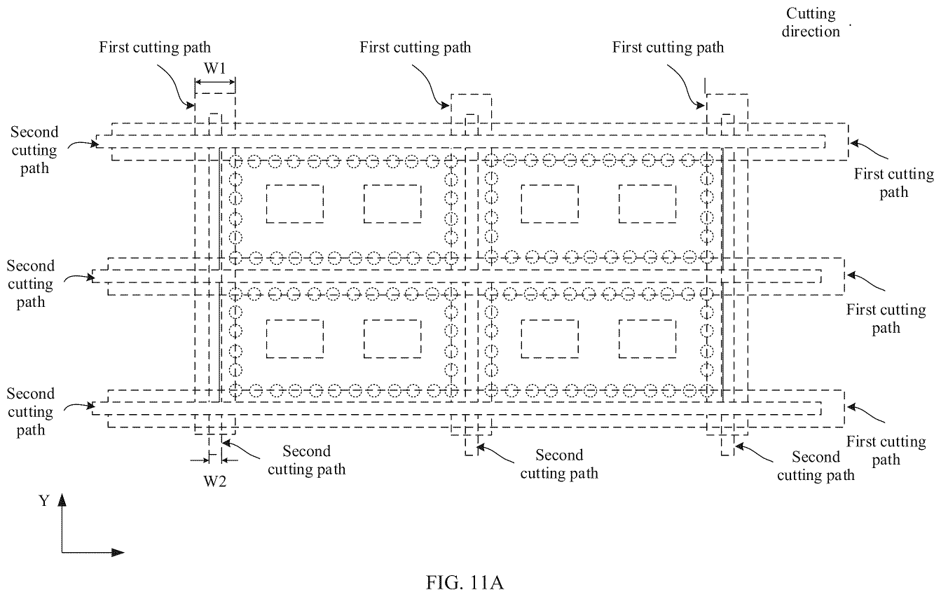

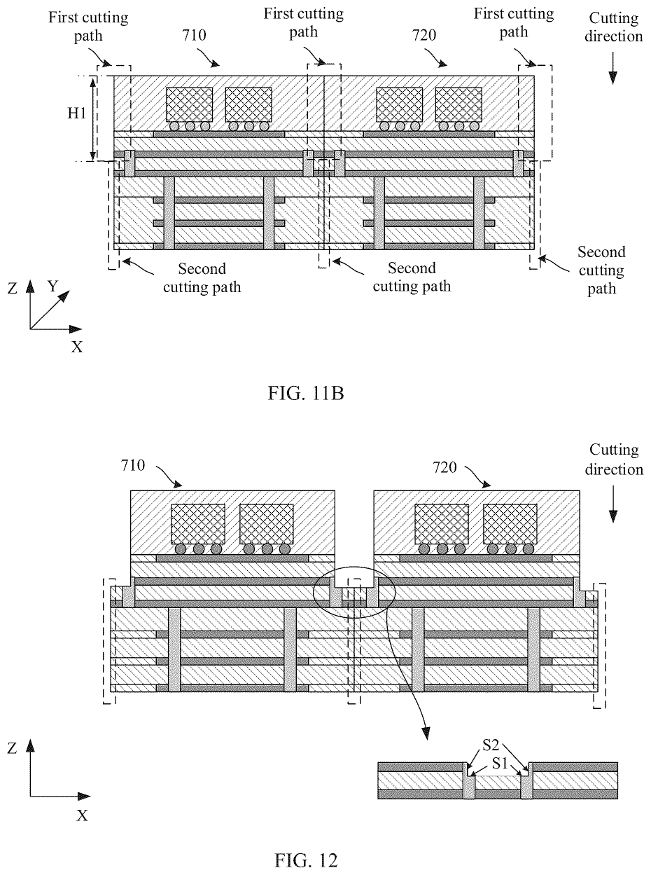

In some possible implementations, as shown in FIG. 11A and FIG. 11B, a first cutting path represents a cutting path in a first cutting process, and the second cutting path represents a cutting path in a second cutting process. The integrated package structure is cut into a plurality of independent single-piece package structures by using two cutting operations. The edge of the first cutting path intersects the area in which the cross section of the first conductive column 15 is located, a width W1 of the first cutting path is greater than a width W2 of the second cutting path, and a depth H1 of the first cutting path is greater than a distance between an upper end face of the first conductive column 15 and the top surface of the substrate, and is less than a distance between a lower end face of the first conductive column 15 and the top surface of the substrate. The upper end face is an end face that is of the first conductive column 15 and that is close to the top surface of the substrate, and the lower end face is an end face that is of the first conductive column 15 and that is away from the top surface of the substrate. In other words, the first cutting path intersects the first conductive column 15, but the first conductive column is not completely included in the first cutting path. In this way, the first conductive column 15 can expose one surface that faces the top surface of the substrate and one surface that faces the first cutting path, and the two surfaces are connected to each other, so that a “right-angle-shaped” corner is formed. In addition, a symmetry axis between two side edges of the first cutting path is the same as a symmetry axis between two side edges of the second cutting path. The two side edges of the first cutting path and the two side edges of the second cutting path are symmetric about a same straight line, and the width W1 of the first cutting path is greater than the width W2 of the second cutting path.

FIG. 12 shows an integrated package structure obtained after the first cutting is performed, along the first cutting path, on the integrated package structure shown in FIG. 7B. It can be learned that the first conductive column 15 exposes a surface S1 that faces the top surface of the substrate and a surface S2 that faces the outer side of the substrate. It should be further noted that the cut surface generated by the first cutting process includes, an outer side surface exposed by the molding 3, the surface S1, and an outer side surface that is exposed by the substrate 1 and that is located between the surface S1 and the top surface of the substrate, where the outer side surface exposed by the substrate 1 includes the surface S2.

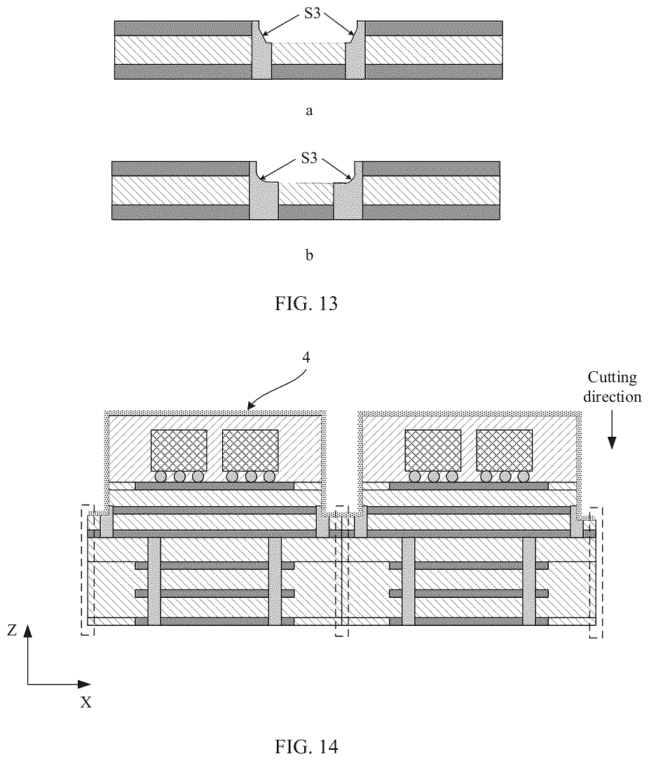

It should be noted that, the first cutting process may further enable the first conductive column 15 to expose a third contact surface, where the first contact surface and the second contact surface may be connected through the third contact surface. It should be understood that, based on different shapes of the cutting tool, third contact surfaces of different forms may be generated. For example, a plane S3 shown in a in FIG. 13 may be generated, or a curved surface S3 shown in b in FIG. 13 may be generated.

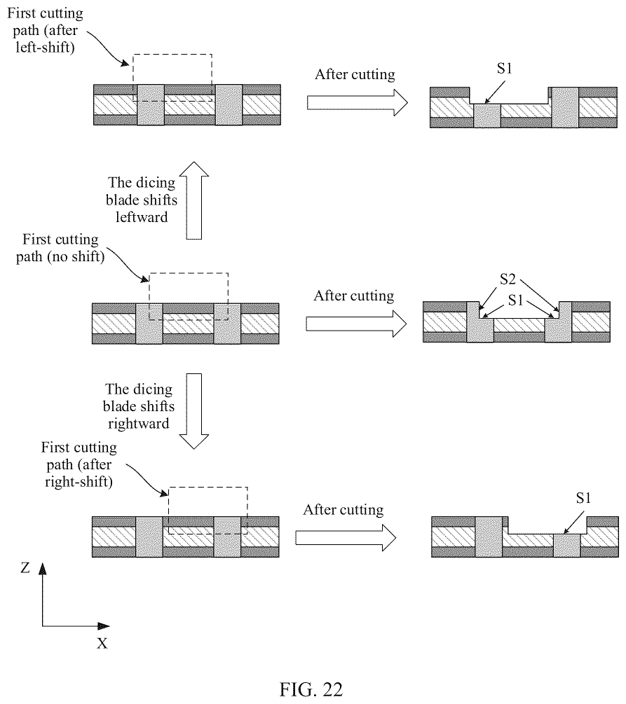

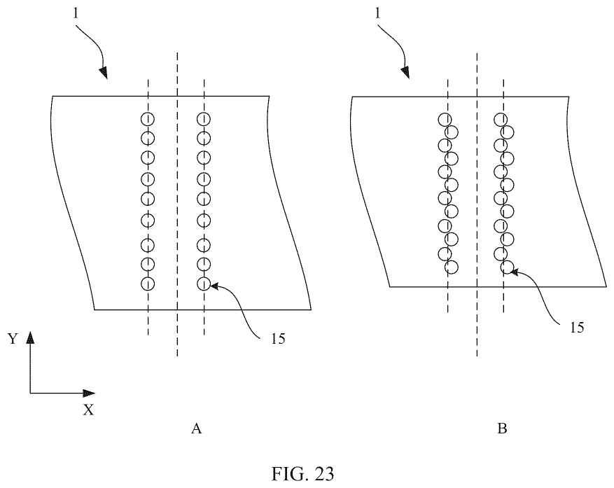

In some other possible implementations, the first cutting path intersects the first conductive column 15, but an edge of the first cutting path does not intersect an area in which a cross section of the first conductive column 15 is located. In other words, the first conductive column is completely included in the first cutting path. In this way, the first conductive column can expose one end face that faces the top surface of the substrate. For details, refer to the case 2 shown in FIG. 22.

With reference to FIG. 14, for the integrated package structure shown in FIG. 12, the shielding layer 4 is formed on the upper surface of the molding 3 and the cut surface that is generated through the first cutting, so that the shielding layer 4 covers outside the chip 2, and is connected to the first conductive column 15 through the surface S1 and the surface S2, that is, the integrated package structure shown in FIG. 14. It can be learned that the shielding layer 4 is in contact with the first conductive column 15 through the surface S1 and the surface S2 that are exposed by the first conductive column 15.

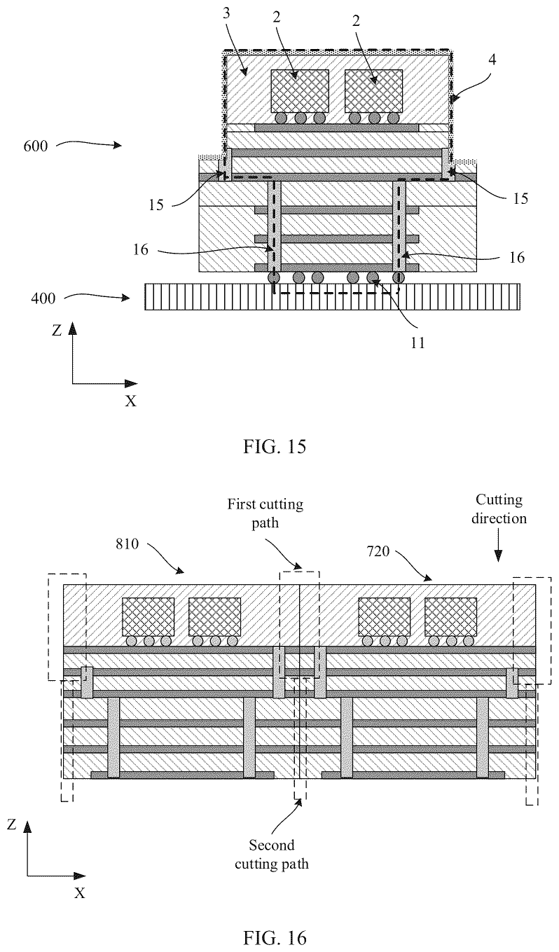

Then, the second cutting is performed on the integrated package structure shown in FIG. 14. Because the symmetry axis between the two side edges of the first cutting path is the same as the symmetry axis between the two side edges of the second cutting path, and the width W1 of the first cutting path is greater than the width W2 of the second cutting path, the second cutting can ensure that the surface S1 is not lost, and a plurality of single-piece package structures can be completely separated, to obtain the chip package structure 600 shown in FIG. 15. It is easily understood that, after the second cutting, a “step-shaped” corner is formed between the surface S1 and the surface S2. The surface S1 and the surface S2 herein are respectively the first contact surface and the second contact surface.

As shown in FIG. 15, in the chip package structure 600 provided in this embodiment, for positions/extending manners and a quantity of the metal layers 12 and quantities and positions of the first conductive columns 15 and the second conductive columns 16 of the chip package structure 600, refer to the description of the package structure 710 in FIG. 7B. Details are not described herein again. It should be emphasized that, in the chip package structure 600, the shielding layer 4 is formed on the upper surface of the molding 3, the first contact surface (S1), and the side surface area that is of the substrate 1 and that is located between the first contact surface (S1) and the top surface of the substrate, and is connected to the first conductive column 15 through the first contact surface (S1) and the second contact surface (S2). The metal layer through which the first conductive column 15 runs is connected to the metal layer on the bottom surface of the substrate through the second conductive column 16, and the grounding circuit in the metal layer on the bottom surface of the substrate 1 is connected to the grounding circuit in the mainboard 400. In this way, the electromagnetic shielding cavity shown by black dashed lines in FIG. 15 is formed.

In the foregoing manufacturing process, two cutting operations may be performed in a manner such as wire cutting, saw blade cutting, or laser cutting. The shielding layer may be formed by using a film forming process such as sputtering, electroplating, and spraying. The electromagnetic shielding material may be a composite material formed by resin, a diluent, an additive, a conductive filler, and the like.

The foregoing manufacturing process may bring the following technical effects:

Based on the design of the integrated package structure and the design of the cutting line position, there are only some of the metal layers of the substrate below the cutting line. Therefore, not all the metal layers of the substrate are cut, so that a cutting tool loss can be reduced, to reduce costs. That is, the foregoing manufacturing process can eliminate the “disadvantage 1” mentioned above.

The cutting process is performed in two steps, and the cutting depth during the first cutting is within the length range of the first conductive column 15. Therefore, even if the dicing blade shifts, the first conductive column 15 can expose the first contact surface, to ensure that the shielding layer can definitely be connected to the first conductive column through the first contact surface, and then connected to the metal layer on the bottom surface of the substrate through the first conductive column, thereby implementing grounding. In other words, the foregoing manufacturing process can eliminate the “disadvantage 2” mentioned above.

The cutting process is performed in two steps, and the shielding layer 4 is formed before the second cutting, that is, the shielding layer 4 is formed when the plurality of single-piece package structures is still connected as a whole. Therefore, the plurality of single-piece package structures does not need to be re-arranged. In other words, the foregoing manufacturing process can eliminate the “disadvantage 3” mentioned above.

The two cutting operations with different cutting widths and control over the cutting depth during the first cutting can enable the first conductive column to expose the first contact surface (S1). When the shielding layer is formed through sputtering, the shielding layer deposited on the first contact surface is thicker, so that contact reliability between the shielding layer and the first conductive column is higher and resistance is lower, thereby achieving better shielding effect and better reliability. In other words, compared with contact between the shielding layer and the side surface that faces the outer side of the substrate, contact between the shielding slayer and the first contact surface (S1) that faces the top surface of the substrate is better. In this example, the shielding layer and the first contact surface are not easily out of contact with each other. In addition, by performing two cutting operations with different cutting widths and controlling the cutting depth during the first cutting, a “step-shaped” corner may be further formed on the first conductive column 15. In this way, the shielding layer may be further formed on another surface of the “step-shaped” corner, that is, the second contact surface, so that the shielding layer can be in contact with two surfaces of the first conductive column. It is easily understood that, compared with a connection implemented through contact on one surface, a connection implemented through contact on two surfaces has better effect. In other words, the foregoing manufacturing process can eliminate the “disadvantage 4” mentioned above.

The cutting process is performed in two steps, and the shielding layer 4 is formed before the second cutting, that is, the shielding layer 4 is formed when the plurality of single-piece package structures is still connected as a whole, and the metal layer and the solder ball 11 on the bottom surface of the substrate 1 herein are not exposed in the process environment. Therefore, the electromagnetic shielding material is not sputtered/sprayed onto the metal layer and the solder ball 11 on the bottom surface of the substrate 1. In other words, the foregoing manufacturing process can eliminate the “disadvantage 5” mentioned above.

The shielding layer is formed only on the outer surface of the molding 3, the first contact surface (S1), and the side surface area that is of the substrate and that is located between the first contact surface and the top surface of the substrate. Compared with forming a shielding layer in all side surface areas of the substrate, most of outer side surfaces of the substrate are not covered by the shielding layer, so that a risk that shielding performance is reduced due to detachment of the shielding layer caused by collision is reduced. In other words, the foregoing manufacturing process can eliminate the “disadvantage 6” mentioned above.

In addition, in the chip package structure 600 shown in FIG. 15, the first-type metal layers and the first conductive columns 15 are located on a side that is of the core plate 141 and that is close to the chip 2, and the second-type metal layers and the second conductive columns 16 are located on a side that is of the core plate 141 and that is away from the chip 2. In other words, the core plate 141 divides the substrate 1 into two parts: an upper part and a lower part. The first-type metal layers and the first conductive columns 15 are located on the upper part of the substrate, and the second-type metal layers and the second conductive columns 16 are located on the lower part of the substrate. In this way, the side surface area that is of the substrate 1 and that needs to be covered by the shielding layer 4 can be reduced, so as to reduce a possibility that the shielding layer 4 falls off due to poor reliability of a combination between the shielding layer 4 and the substrate 1, that is, enhancing reliability of the electromagnetic shielding cavity.

Further, assuming that the first-type metal layers and the first conductive columns 15 are located on the lower part of the substrate, it means that the shielding layer 4 needs to cover a side surface area corresponding to the upper part of the substrate 1 and a side surface area of the core plate 141 before extending to the first contact surface exposed by the first conductive column 15. If the first-type metal layers and the first conductive columns 15 are located on the upper part of the substrate 1, the shielding layer 4 does not need to cover the foregoing side surface areas, and therefore side surface areas that are of the substrate 1 and that need to be covered by the shielding layer 4 can be reduced.

It is easily understood that chip package structures of different structures are obtained after integrated package structures of different structural designs are processed by using the manufacturing method provided in the foregoing embodiment. The following describes other possible chip package structures 600 with reference to the integrated package structures shown in FIG. 8 and FIG. 9.

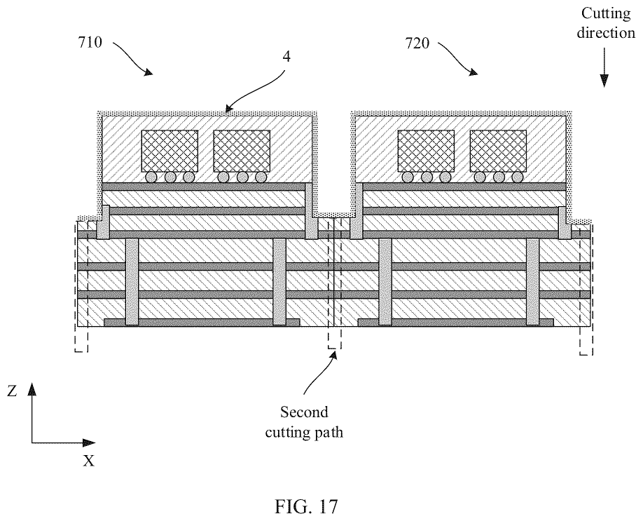

FIG. 16 is a diagram of a cutting path when the integrated package structure shown in FIG. 8 is processed by using the foregoing manufacturing method. For descriptions of positions, widths, and depths of the first cutting path and the second cutting path, refer to the foregoing embodiment. Details are not described herein again. FIG. 17 is a diagram of a structure obtained after the first cutting is performed on the integrated package structure and after the shielding layer 4 is formed on the integrated package structure. For descriptions about a forming position of the shielding layer 4 and a contact manner between the shielding layer 4 and the first conductive column 15, refer to the foregoing embodiment. Details are not described herein again. FIG. 18 shows a chip package structure 600 obtained after the second cutting is performed on the integrated package structure. As shown in FIG. 18, in the chip package structure 600, the shielding layer 4 is connected to the first conductive column 15 through the “step-shaped” corner exposed by the first conductive column 15, the metal layer through which the first conductive column 15 runs is connected to the metal layer on the bottom surface of the substrate through the second conductive column 16, and the grounding circuit in the metal layer on the bottom surface of the substrate is connected to the grounding circuit in the mainboard 400. In this way, the electromagnetic shielding cavity shown by black dashed lines in FIG. 18 is formed. Electronic components such as the chip are all mounted in the electromagnetic shielding cavity. Different from the chip package structure 600 shown in FIG. 15, in FIG. 18, each metal layer extends outward to peripheral edges of the substrate, and the first conductive columns 15 located on different sides of the substrate run through different quantities of metal layers.

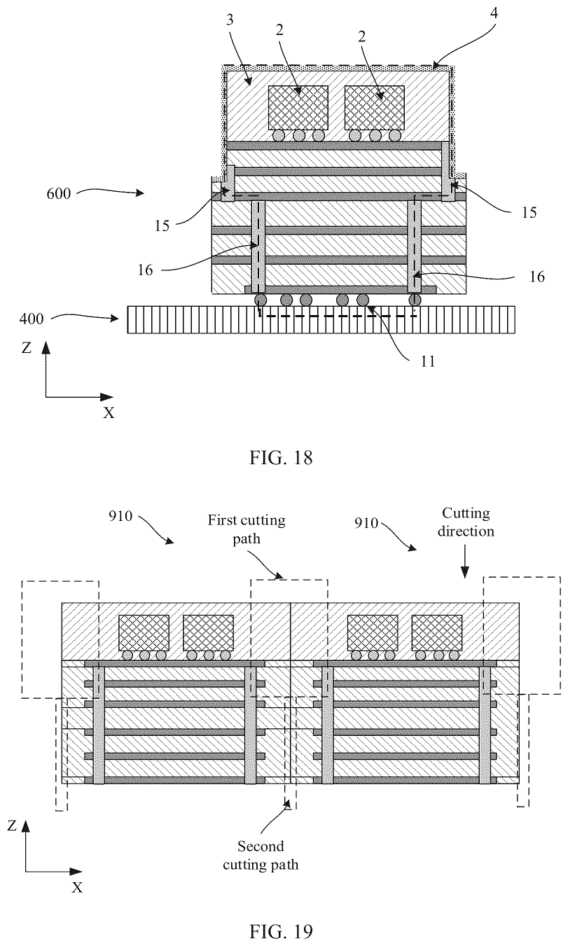

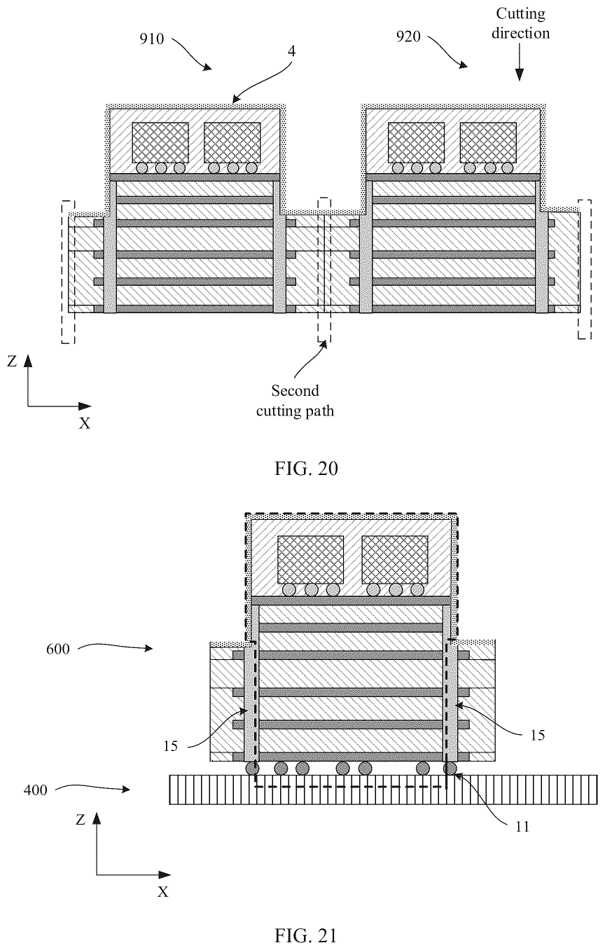

FIG. 19 is a diagram of a cutting path when the integrated package structure shown in FIG. 9 is processed by using the foregoing manufacturing method. For descriptions of positions, widths, and depths of the first cutting path and the second cutting path, refer to the foregoing embodiment. Details are not described herein again. FIG. 20 is a diagram of a structure obtained after the first cutting is performed on the integrated package structure and after the shielding layer 4 is formed on the integrated package structure. For descriptions about a forming position of the shielding layer 4 and a contact manner between the shielding layer 4 and the first conductive column 15, refer to the foregoing embodiment. Details are not described herein again. FIG. 21 shows a chip package structure 600 obtained after the second cutting is performed on the integrated package structure. As shown in FIG. 21, none of the metal layers in the chip package structure 600 extends to the peripheral edge of the substrate.

Considering that the dicing blade may shift in the actual cutting process, a slight error between the actual cutting path and a cutting path in the process design is further caused. As shown in FIG. 22, it is easily understood that a shift of the dicing blade means a shift of a cutting path, and/or a position of an edge of the cutting path changes. For the integrated package structure provided in this embodiment, during the first cutting, impact directly generated by the shift (including shift leftward, left-shift for short below, and shift rightward, right-shift for short below) of the dicing blade is that the first cutting path does not intersect the first conductive column, or the edge of the first cutting path does not intersect the area in which the cross section of the first conductive column is located. In this case, two cases shown in FIG. 22 may occur. In one case, the first conductive column is not cut at all. As a result, after the cutting is completed, the first conductive column does not expose any surface. In the second case, the first conductive column is cut to expose a complete end face of the first conductive column, but the “right-angle-shaped” corner described above is not formed, and therefore no “step-shaped” corner is formed after the second cutting.

Therefore, to ensure that the actual first cutting path still intersects the first conductive column or ensure that the edge of the first cutting path still intersects the area in which the cross section of the first conductive column is located after the dicing blade shifts, in some embodiments, in the integrated package structure, for a single-piece package structure, a plurality of first conductive columns located on a same side of the substrate of the integrated package structure may not be completely located on a same straight line, or in other words, these first conductive columns may be disposed in a staggered manner relative to a straight line, and a distance between each first conductive column and the straight line is less than a distance threshold, in this example, these first conductive columns are distributed in a specified area range. In this case, even if the dicing blade shifts within the area range, it can be ensured that some of the first conductive columns are cut.

FIG. 23 is a diagram of distribution of first conductive columns in an integrated package structure according to an embodiment. In distribution shown in A in FIG. 23, a plurality of first conductive columns 15 located on a same side of the substrate 1 is distributed in an array at intervals, and are all located on a same straight line. In distribution shown in B in FIG. 23, a plurality of first conductive columns 15 located on a same side of the substrate 1 is disposed in a staggered manner relative to a same straight line, and a distance between each first conductive column 15 and the straight line is less than a distance threshold. In this way, even if the dicing blade shifts to some extent, it can be ensured that the first conductive column can be cut, and it is ensured that at least some of the first conductive columns expose the foregoing “step-shaped” corner.

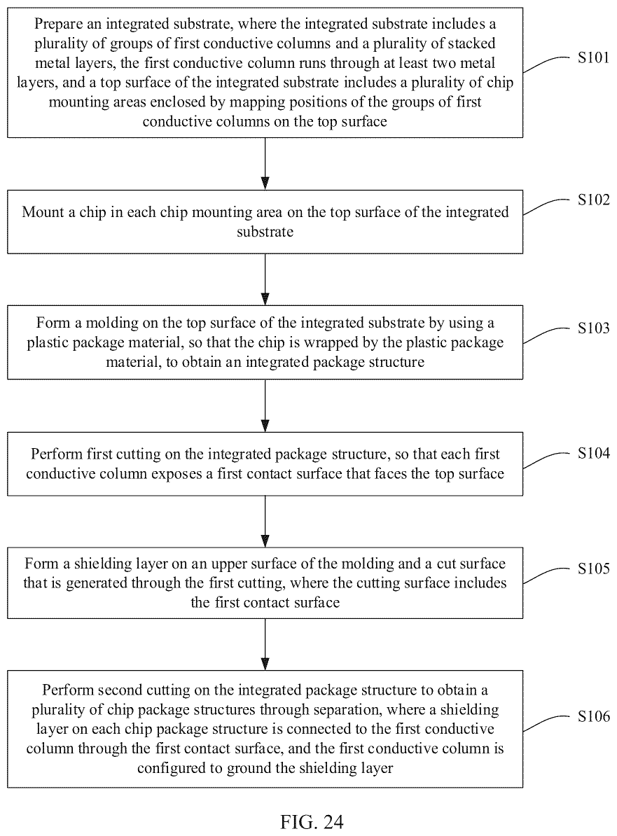

FIG. 24 is a flowchart of a method for manufacturing a chip package structure according to an embodiment. As shown in FIG. 24, the method may include the following steps.

S101: Prepare an integrated substrate, where the integrated substrate includes a plurality of groups of first conductive columns and a plurality of stacked metal layers, the first conductive column runs through at least two metal layers, and a top surface of the integrated substrate includes a plurality of chip mounting areas enclosed by mapping positions of the groups of first conductive columns on the top surface.

It is easily understood that the integrated substrate herein is the substrate of the foregoing integrated package structure. With reference to FIG. 7A, the integrated substrate includes four groups of first conductive columns, and mapping positions of each group of first conductive columns on the top surface of the integrated substrate enclose a rectangular area, that is, a chip mounting area.

In a process of preparing the integrated substrate, the core plate 141 shown in FIG. 7B is first prepared by using an insulation material. Then, on one side of the core plate 141, the plurality of first metal layers is formed, and the plurality of groups of first conductive columns that runs through the at least two first metal layers are formed, where the plurality of first metal layers is stacked in a direction perpendicular to the top surface of the integrated substrate and is separated through a first insulation layer. It can be learned from FIG. 7B that, in this example, a first metal layer L3 is formed on a surface on a side of the core plate 141, a first insulation layer is formed on a surface that is of the first metal layer L3 and that is on a side away from the core plate 141, another first metal layer L2 is formed on a surface that is of the first insulation layer and that is on a side away from the first metal layer L3, and four groups of first conductive columns 15 are also formed, where each first conductive column 15 runs through L2 and L3. Mapping positions of each group of first conductive columns 15 on the top surface of the integrated substrate enclose a chip mounting area, and four chip mounting areas are further formed.

In addition, each group of first conductive columns 15 are divided into a plurality of parts, and mapping positions of the parts of the first conductive columns on the top surface of the integrated substrate are located on all sides of the chip mounting area, where mapping positions of a first part of the first conductive columns on the top surface are distributed on a straight line or distances between the straight line and the mapping positions are within a preset distance range, and the first part is any one of the plurality of parts. In the example shown in FIG. 7A, each group of first conductive columns are divided into four parts, and mapping positions of the four parts of the first conductive columns on the top surface of the integrated substrate form four sides of the rectangular chip mounting area. Each part of the first conductive columns is strictly distributed along a straight line or distributed in a staggered manner along a straight line.

In addition, a plurality of groups of second metal layers is formed on the other side of the core plate 141, where different groups of second metal layers are stacked in the direction perpendicular to the top surface of the substrate, and are separated through a second insulation layer, a plurality of second metal layers in a same group of second metal layers is formed in a plurality of preset areas on a same surface, and a distance between an edge of the second metal layer in any preset area and an edge of the preset area is the foregoing D2, and the second insulation layer has a protruding part extending in a direction perpendicular to the surface, and the second metal layers on the same surface are separated through the protruding part, and the surface herein includes a surface on the other side of the core plate and a surface that is of the second insulation layer and that is away from the core plate, that is, a surface used for forming the second metal layers, and the plurality of preset areas on the surface are respectively areas enclosed by the mapping positions of the groups of first conductive columns on the surface. As shown in FIG. 7B, three groups of second metal layers are stacked in the direction perpendicular to the top surface of the substrate. The first group of second metal layers are formed on a surface on the other side of the core plate 141, the second group of second metal layers are formed on a surface that is of the second insulation layer and that is on a side away from the core plate 141, and the third group of second metal layers are formed on a surface that is of the second insulation layer and that is on a side away from the core plate 141. The second insulation layer has a protruding part, and the second metal layers in the first group, the second group, and the third group of second metal layers are separated through the protruding part.

In a possible implementation, S101 further includes forming a plurality of groups of second conductive columns. As shown in FIG. 7B, each of the plurality of groups of second conductive columns runs through a plurality of second metal layers, and is connected to at least one first metal layer through which the first conductive column runs and the metal layer located on the bottom surface of the substrate. Mapping positions of a same group of second conductive columns on the foregoing surface (that is, a surface on which a group of second metal layers are formed) are located in a same preset area. Optionally, a distance between a mapping position of the second conductive column in a preset area and the edge of the preset area is the foregoing D1.

S102: Mount a chip in each chip mounting area on the top surface of the integrated substrate.

Still with reference to FIG. 7A, four groups of chips are respectively mounted in the foregoing four chip mounting areas. In the example shown in FIG. 7A, each group of chips include two chips 2, and each chip 2 is electrically connected to the metal layer on the top surface of the integrated substrate.

S103: Form a molding on the top surface of the integrated substrate by using a plastic package material, so that the chip is wrapped by the plastic package material, to obtain an integrated package structure.

With reference to FIG. 7B, the molding 3 is formed on the top surface of the integrated substrate by using S103.

The integrated package structures in embodiments may be manufactured based on S101, S102, and S103. For example, any integrated package structure shown in FIG. 7A to FIG. 9 may be manufactured. In other words, a plurality of integrally formed substrates and included in any integrated package structure may be the integrated substrate manufactured in S101, and in any integrated package structure, a chip disposed on a top surface of each substrate may be a chip mounted in each chip mounting area by using S102.

Alternatively, it may be understood that S101, S102, and S103 may be used as pre-steps of “obtaining an integrated package structure” in the manufacturing method provided in the foregoing embodiment, that is, process steps that need to be performed before “obtaining an integrated package structure”, or may be used as detailed steps of “obtaining an integrated package structure”, that is, an example of an implementation process of “obtaining an integrated package structure” includes S101, S102, and S103.

Based on this, an embodiment further provides a method for manufacturing an integrated package structure. The method for manufacturing an integrated package structure includes S101, S102, and S103. In other words, in some embodiments, S101, S102, and S103 may constitute a method for manufacturing an integrated package structure, and are not limited to forming the method for manufacturing a chip package structure provided in this embodiment together with the following S104, S105, and S106.

S104: Perform first cutting on the integrated package structure, so that each first conductive column exposes a first contact surface that faces the top surface.

S105: Form a shielding layer on an upper surface of the molding and a cut surface that is generated through the first cutting, where the cut surface includes the first contact surface.

S106: Perform second cutting on the integrated package structure to obtain a plurality of chip package structures through separation, where a shielding layer on each chip package structure is connected to the first conductive column through the first contact surface, and the first conductive column is configured to ground the shielding layer.

For a an example of process procedure of S104 to S106, refer to content in the foregoing embodiments. Details are not described herein again.

The foregoing descriptions are merely example implementations, but are not intended to limit the protection scope of this disclosure. Any variation or replacement readily figured out by a person skilled in the art within the technical scope described shall fall within the protection scope of this disclosure. Therefore, the protection scope of this disclosure shall be subject to the protection scope of the claims.

1. A chip package structure, comprising:
a substrate comprising:
an outer side;
a top surface; and
a plurality of metal layers that are stacked, wherein the metal layers comprise a first metal layer disposed on the top surface;
a first conductive column, wherein the first conductive column runs through at least two metal layers of the metal layers, and wherein the first conductive column comprises a first contact surface that is exposed to the outer side and that faces the top surface;
a chip disposed on the top surface and electrically connected to the first metal layer; and
a shielding layer located outside the chip, electrically connected to the first conductive column through the first contact surface, and configured to be grounded.

2. The chip package structure of claim 1, wherein the first conductive column further comprises a second contact surface that is exposed to the outer side, wherein the second contact surface is coupled to the first contact surface, and wherein the shielding layer is electrically connected to the first conductive column through the first contact surface and the second contact surface.

3. The chip package structure of claim 1, further comprising a molding located on the top surface, wherein the chip is wrapped in the molding, and wherein the shielding layer is located between the first contact surface and the top surface and covers a surface of the molding, the first contact surface, and a side surface area of the substrate.

4. The chip package structure of claim 1, wherein the shielding layer is grounded through one of the at least two metal layers through which the first conductive column runs.

5. The chip package structure of claim 4, wherein one of the at least two metal layers is connected to a second metal layer of the metal layers and on a bottom surface of the substrate, and wherein the second metal layer is configured for grounding.

6. The chip package structure of claim 1, further comprising a second conductive column, wherein the at least two metal layers are located inside the substrate, wherein the metal layers comprise a second metal layer on a bottom surface of the substrate wherein one of the at least two metal layers is connected to the second metal layer through the second conductive column and in a direction parallel to the top surface, and wherein a distance between the second conductive column and a side of the first conductive column distal from the outer side of the substrate is greater than a first distance.

7. The chip package structure of claim 6, further comprising an insulation layer separating the at least two metal layers.

8. The chip package structure of claim 7, wherein the metal layers comprise a plurality of third metal layers and at least one fourth metal layer that are consecutively disposed in a direction parallel to the top surface, wherein edges of the third metal layers extend to an outer edge of the substrate, wherein the first conductive column runs through the third metal layers, wherein, in the direction, a third distance between an edge of the fourth metal layer and a side of the first conductive column distal from the outer side is greater than a second distance, and wherein the second distance is less than the first distance.

9. The chip package structure of claim 8, further comprising a plurality of fifth metal layers, wherein at least two sixth metal layers of the fifth metal layers are consecutively disposed, and wherein the second conductive column runs through the at least two sixth metal layers.

10. The chip package structure of claim 8, wherein the insulation layer comprises a core plate, wherein the first conductive column is located on a first side of the core plate proximal to the chip, and wherein the fourth metal layer is located on a second side of the core plate distal from the chip.

11. The chip package structure of claim 1, further comprising a plurality of conductive columns disposed on a first side of the substrate, wherein the plurality of conductive columns comprise the first conductive column and is distributed on a first straight line parallel to a boundary line of the first side.

12. The chip package structure of claim 1, wherein the substrate further comprises a bottom surface, wherein the metal layers further comprise a second metal layer disposed on the bottom surface, and wherein the first metal layer and the second metal layer comprise metal wiring layers.

13. An electronic device, comprising:
chip package structure; comprising:
a substrate comprising:
an outer side;
a top surface; and
a plurality of metal layers that are stacked, wherein the metal layers comprise a first metal layer disposed on the top surface;
a mainboard located on a first surface of the substrate;
a first conductive column, wherein the first conductive column runs through at least two metal layers of the metal layers, and wherein the first conductive column comprises a first contact surface that is exposed to the outer side of the and that faces the top surface;
a chip disposed on the top surface, and electrically connected to a metal layer on the top surface; and
a shielding layer located outside the chip, electrically connected to the first conductive column through the first contact surface, and configured to be grounded.

14. The electronic device of claim 13, wherein the first conductive column further comprises a second contact surface that is exposed to the outer side, wherein the second contact surface is coupled to the first contact surface, and wherein the shielding layer is electrically connected to the first conductive column through the first contact surface and the second contact surface.

15. The electronic device of claim 13, further comprising a molding located on the top surface, wherein the chip is wrapped in the molding, and wherein the shielding layer is located between the first contact surface and the top surface and covers a surface of the molding, the first contact surface, and a side surface area of the substrate.

16. The electronic device of claim 13, wherein the shielding layer is grounded through one of the at least two metal layers through which the first conductive column runs.

17. The electronic device of claim 13, wherein one of the at least two metal layers is connected to a second metal layer of the metal layers and on a bottom surface of the substrate, and wherein the second metal layer is configured for grounding.

18. The electronic device of claim 13, further comprising a second conductive column, wherein the at least two metal layers are located inside the substrate, wherein the metal layers comprise a second metal layer on a bottom surface of the substrate, wherein one of the at least two metal layers is connected to the second metal layer through the second conductive column and in a direction parallel to the top surface, and wherein a distance between the second conductive column and a side that is of the first conductive column and that is distal from the outer side of the substrate is greater than a first distance.

19. The electronic device of claim 13, further comprising an insulation layer separating the at least two metal layers.

20. The electronic device of claim 13, wherein the metal layers comprise a plurality of third metal layers and at least one fourth metal layer that are consecutively disposed in a direction parallel to the top surface, wherein edges of the third metal layers extend to an outer edge of the substrate, wherein the first conductive column runs through the third metal layers, wherein in the direction, a third distance between an edge of the fourth metal layer and a side of the first conductive column distal from the outer side is greater than a second distance, and wherein the second distance is less than the first distance.
